(19) United States
(12) Patent Application Publication
(10) Pub. No.: US 2024/0298552 A1
(43) Pub. Date: Sep. 5, 2024

(54) SWITCH BASED ON A PHASE-CHANGE MATERIAL

(71) Applicant: Commissariat à I'Énergie Atomique et aux Énergies Alternatives, Paris (FR)

(72) Inventors: Denis Mercier, Grenoble Cedex (FR); Bruno Reig, Grenoble Cedex (FR)

(73) Assignee: Commissariat à I'Énergie Atomique et aux Énergies Alternatives, Paris (FR)

(21) Appl. No.: 18/590,072

(22) Filed: Feb. 28, 2024

(30) Foreign Application Priority Data
Mar. 3, 2023 (FR) 2302011

(51) Int. Cl. H10N 70/20; H10N 70/00

(52) U.S. Cl. CPC H10N 70/231; H10N 70/823; H10N 70/8413; H10N 70/8828

(57) ABSTRACT

The present description concerns a switch including: first, second, third, and fourth conductive regions; a first region made of a phase-change material coupling the first and second conductive regions; a second region made of a phase-change material coupling the second and third conductive regions; and a third region made of a phase-change material coupling the second and fourth conductive regions.

### TECHNICAL FIELD

The present disclosure generally concerns electronic devices. The present disclosure more particularly concerns switches based on a phase-change material capable of alternating between a crystalline, electrically-conductive phase and an amorphous, electrically-insulating phase.

### PRIOR ART

Various applications take advantage of switches based on a phase-change material to allow or prevent the flowing of an electric current in a circuit. Such switches may in particular be implemented in radio frequency communication applications, for example to switch an antenna between transmit and receive modes, to activate a filter corresponding to a frequency band, etc.

Existing switches based on a phase-change material however suffer from various disadvantages.

### SUMMARY OF THE INVENTION

There exists a need to improve existing switches based on a phase-change material.

For this purpose, an embodiment provides a switch comprising:
first, second, third, and fourth electrodes;
a first region made of a phase-change material coupling the first and second electrodes;
a second region made of a phase-change material coupling the second and third electrodes; and
a third region made of a phase-change material coupling the second and fourth electrodes.

According to an embodiment, the switch further comprises first, second, and third heater elements respectively located in front of the first, second, and third regions of phase-change material, each heater element being electrically insulated from said region located in front of it.

According to an embodiment, the third heater element is intended to be controlled independently from the first and second heater elements.

According to an embodiment, the first and second heater elements are intended to be simultaneously controlled.

According to an embodiment, the first and second heater elements are series-connected between two control electrodes.

According to an embodiment, the first, second, and third regions of phase-change material are made of a chalcogenide material.

According to an embodiment, each of the first, second, and third regions of phase-change material is made of germanium telluride or of germanium-antimony-telluride.

According to an embodiment, the third region of phase-change material has a volume smaller than that of the first and second regions of phase-change material.

According to an embodiment, the first and second regions of phase-change material have, in top view, different areas.

According to an embodiment, the first and second regions of phase-change material have, along the switch conduction direction, a same lateral dimension.

According to an embodiment, the first and second regions of phase-change material have, along a direction orthogonal to the switch conduction direction, different lateral dimensions.

An embodiment provides a device comprising a switch such as described and a ground plane having the fourth electrode of the switch connected thereto.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1A and FIG. 1B are simplified and partial views, respectively a top view and a cross-section view along plane AA of FIG. 1A, of an example of a switch based on a phase-change material according to an embodiment;

FIG. 2A, FIG. 2B, and FIG. 2C are simplified and partial top views illustrating different states of the switch of FIGS. 1A and 1B;

FIG. 3 is a circuit diagram equivalent to the switch of FIGS. 1A and 1B;

FIG. 4 is a simplified and partial top view of an example of a microstrip line comprising the switch of FIGS. 1A and 1B according to an embodiment;

FIG. 5 is a simplified and partial top view of an example of a coplanar line comprising the switch of FIGS. 1A and 1B according to an embodiment;

FIG. 6 is a simplified and partial top view of an example of a switch based on a phase-change material according to an embodiment; and

FIG. 7 is a simplified and partial top view of an example of a switch based on a phase-change material according to an embodiment.

### DESCRIPTION OF EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the circuits for controlling the switches based on a phase-change material and the applications in which such switches may be provided have not been detailed, the described embodiments and variants being compatible with circuits controlling switches based on a phase-change material and with usual applications implementing switches based on a phase-change material.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

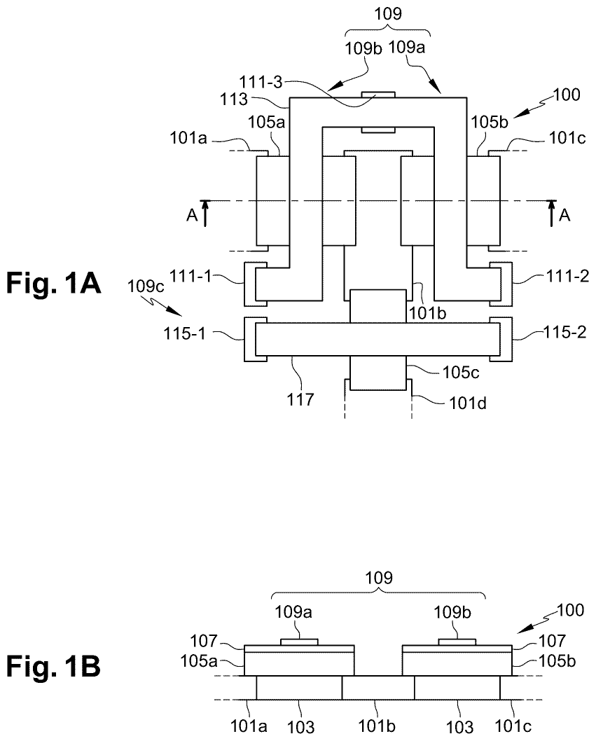

FIG. 1A and FIG. 1B are simplified and partial views, respectively a top view and a cross-section view along plane AA of FIG. 1A, of an example of a switch 100 based on a phase-change material according to an embodiment.

In the shown example, switch 100 comprises coplanar conductive regions 101a, 101b, 101c, and 101d. Conductive regions 101a and 101c are located on either side of conductive region 101b. In the orientation of FIG. 1A, conductive regions 101a and 101c are located at the left and right ends, respectively, of switch 100. Conductive region 101b is laterally interposed between conductive regions 101a and 101c. Conductive region 101d is located in front of conductive region 101b. In the orientation of FIG. 1A, conductive region 101d is located at the lower end of switch 100.

Conductive regions 101a and 101c are, for example, conduction electrodes of switch 100, for example intended to be connected to a radio-frequency communication circuit, not detailed. Conductive region 101b is for example an intermediate region, or central region. Conductive region 101d is for example a reference electrode intended to be taken to a reference potential, for example the ground. Conductive region 101d is for example connected to ground.

As an example, conductive regions 101a, 101b, 101c, and 101d are made of a conductive material, for example a metal or a metal alloy. Each conductive region 101a, 101b, 101c, 101d may have a single-layer or multi-layer structure. To simplify the forming of switch 100, conductive regions 101a, 101b, 101c, and 101d for example have substantially identical structures and compositions, to within manufacturing dispersions. As an example, each conductive region 101a, 101b, 101c, and 101d has, in top view, a periphery of substantially rectangular shape. This example is however not limiting, and each conductive region 101a, 101b, 101c, 101d may have any shape.

Although this has not been detailed, the conductive regions 101a, 101b, 101c, and 101d of switch 100 are for example located on top of and in contact with a surface of an insulating layer, for example made of silicon dioxide, coating a substrate, for example a wafer or a piece of wafer made of a semiconductor material, for example silicon.

In the shown example, an electrically-insulating layer 103 coats the lateral surfaces of conductive regions 101a, 101b, 101c, and 101d and fills the free spaces laterally extending between conductive regions 101a, 101b, 101c, and 101d. Layer 103, not shown in FIG. 1A so as not to overload the drawing, electrically insulates conductive regions 101a, 101b, 101c, and 101d from one another. In the shown example, insulating layer 103 is flush with the upper surface of conductive regions 101a, 101b, 101c, and 101d. As an example, insulating layer 103 is made of silicon dioxide.

In the shown example, switch 100 further comprises regions 105a, 105b, and 105c made of a phase-change material. Regions 105a, 105b, and 105c are separate and each couple two adjacent conductive regions of switch 100. More specifically, in the illustrated example, region 105a couples conductive regions 101a and 101b, region 105b couples conductive regions 101b and 101c, and region 105c couples conductive regions 101b and 101d. In other words, conductive region 101b is coupled to each of the other conductive regions 101a, 101c, and 101d by regions made of a phase-change material 105a, 105b, and 105c, respectively. Each region 105a, 105b, 105c of phase-change material coats the upper surface of a portion of layer 103 laterally extending between the two adjacent conductive regions that it couples, and extends on top of and in contact with a portion of the upper surface of each of said conductive regions. Each region 105a, 105b, 105c of phase-change material has, for example, in top view, a periphery of substantially rectangular shape. This example is however not limiting, and each region 105a, 105b, 105c may have any shape. Regions 105a and 105b are for example intended to transmit a radio frequency signal. As an example, region 105d of phase-change material is connected to a terminal or to a node of application of a reference potential, for example, the ground.

Switch 100 has, in the orientation of FIG. 1A, a general T shape, having its horizontal bar, parallel to a conduction direction of switch 100, comprising conductive regions 101a, 101b, and 101c and regions 105a and 105b of phase-change material, and having its vertical bar, extending along a direction orthogonal to the conduction direction of switch 100, comprising conductive regions 101b and 101d and region 105c of phase-change material. This example is however not limiting, and switch 100 may have any shape. The conduction direction of switch 100 and the direction along which conductive region 101d and region 105c extend may, for example, be oblique.

As an example, each region 105a, 105b, 105c of switch 100 is made of a material called “chalcogenide”, that is, a material or an alloy comprising at least one chalcogen element, for example a material from the family of germanium telluride, antimony telluride, or germanium-antimony-telluride, more commonly designated with acronym “GST”. As a variant, at least one of regions 105a, 105b, 105c may be made of vanadium dioxide.

Region 105c of switch 100 is for example sized differently from regions 105a and 105b. As an example, region 105c has a volume, or an active surface, different from the volume, or from the active surfaces, of each of regions 105a and 105b. As a variant, or complementarily, region 105c may be made of a phase-change material different from that of regions 105a and 105b.

In the orientation of FIG. 1B, the upper surface of each region 105a, 105b, 105c is coated with an electrically-insulating layer 107. As an example, insulating layer 107 is made of a dielectric and thermally-conductive material, for example silicon nitride or aluminum nitride. Insulating layer 107 has not been shown in FIG. 1A so as not to overload the drawing.

In the illustrated example, switch 100 further comprises heater elements 109a, 109b, and 109c located on top of and in contact with the upper surface of layer 107 vertically in line with regions 105a, 105b, and 105c, respectively. In this example, each heater element 109a, 109b, 109c is electrically insulated from the underlying region 105a, 105b, 105c by layer 107. In the shown example, heater elements 109a and 109b each have the shape of a rectangular strip extending along a direction substantially orthogonal to the conduction direction of switch 100, and heater element 109c has the shape of a rectangular strip extending along a direction substantially parallel to the conduction direction of switch 100. In the example illustrated in FIGS. 1A and 1B, heater elements 109a and 109b are adjacent and form a single heater element 109. This enables to heat regions 105a and 105b simultaneously, region 105a then always being in the same state, amorphous or crystalline, as region 105b.

In the example illustrated in FIG. 1A, heater elements 109a and 109b are series-connected between control electrodes 111-1 and 111-2 located on either side of conductive region 101b. More specifically, in the shown example, heater element 109a is connected between control electrode 111-1 and an intermediate control electrode 111-3, and heater element 109b is connected between intermediate control electrode 111-3 and control electrode 111-2. The presence of electrode 111-3 advantageously enables to decrease the control voltages of heater elements 109a and 109b with respect to the voltages which should be applied in the absence of electrode 111-3. However, control electrode 111-3 may, as a variant, be omitted. In the illustrated example, heater elements 109a and 109b form part of a same conductive track 113, for example a metal track, having its left and right ends respectively connected to control electrodes 111-1 and 111-2. At least a portion of the track 113 connecting heater element 109a to heater element 109b is located vertically in line with a region devoid of phase-change material, for example an electrically-insulating region. In the illustrated example, heater elements 109a and 109b are intended to be controlled simultaneously, for example by the application of a first potential difference between electrodes 111-1 and 111-3 and by the application of a second potential difference, for example substantially equal to the first potential difference, between electrodes 111-2 and 111-3. As an example, electrode 111-3 is taken to a reference potential, for example, the ground, and electrodes 111-1 and 111-2 are taken to a high potential.

As a variant, heater elements 109a and 109b may be electrically insulated from each other. In this case, heater elements 109a and 109b are for example formed in separate conductor tracks, insulated from each other and each connected between control electrodes similar to electrodes 111-1 and 111-2. In this case, the control electrodes of each heater element 109a, 109b are for example located on either side of the conduction direction of switch 100. Heater elements 109a and 109b may, in this variant, be simultaneously controlled, for example by the simultaneous application of a potential difference between the control electrodes of each heater element 109a, 109b.

In the shown example, heater element 109c is connected between control electrodes 115-1 and 115-2 and forms part of a conductive track 117, for example a metal track, having its left and right ends respectively connected to the control electrodes 115-1 and 115-2 of heater element 109c. In this example, the track 117 to which heater element 109c belongs is electrically insulated from the track 113 to which heater elements 109a and 109b belong, and control electrodes 115-1 and 115-2 are electrically insulated from control electrodes 111-1 and 111-2. This makes it possible to control heater element 109c independently from heater elements 109a and 109b.

For example, the control electrodes 111-1, 111-2, and 111-3 of the heater elements 109a and 109b of switch 100 are coupled or connected to a first control circuit, and the control electrodes 115-1 and 115-2 of heater element 109c are coupled or connected to a second control circuit, for example separate from the first control circuit. To avoid overloading the drawing, the control circuits of heater elements 109a, 109b, and 109c have not been shown.

Each heater element 109a, 109b, 109c for example has a thickness in the order of 100 nm and a width in the range from few hundred nanometers to a few micrometers. As an example, each heater element 109a, 109b, 109c is made of a metal, for example, tungsten, or of a metal alloy, for example, titanium nitride. Although this has not been shown, switch 100 may be coated with a thermally-insulating layer intended to confine the heat generated by heater elements 109a, 109b, and 109c.

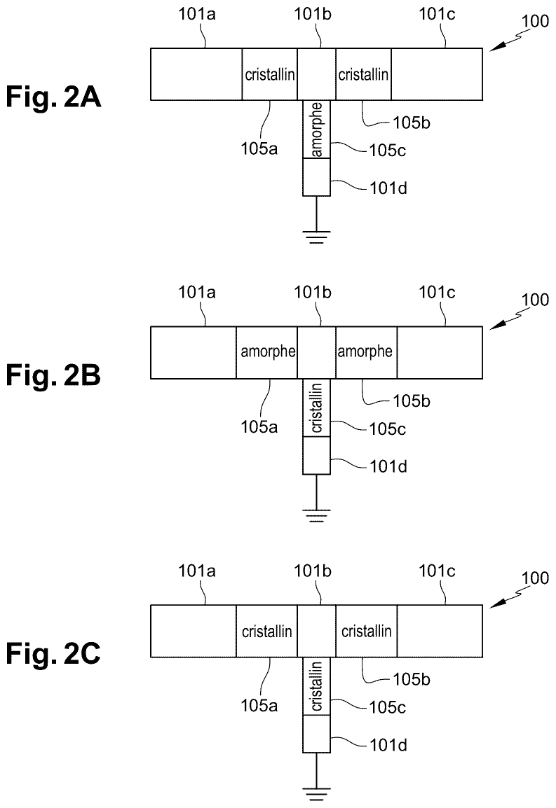

FIG. 2A, FIG. 2B, and FIG. 2C are partial and simplified top views illustrating different states of the switch of FIGS. 1A and 1B.

Generally, phase-change materials are materials capable of alternating, under the effect of a temperature variation, between a crystalline phase and an amorphous phase, the amorphous phase having an electrical resistivity higher than that of the crystalline phase. In the case of switch 100, advantage is taken of this phenomenon to obtain:
a first state (FIG. 2A), called “conducting state”, allowing the flowing of a current between conductive regions 101a, 101b, and 101c, when the material of regions 105a and 105b is in the crystalline phase and when a portion at least of the material of region 105c is in the amorphous phase;
a second state (FIG. 2B), called “reflective non-conducting state”, prevents the flowing of a current between conductive regions 101a and 101c, when at least a portion of the material of regions 105a and 105b is in the amorphous phase and when the material in region 105c is in the crystalline phase; and
a third state (FIG. 2C), called “absorbing non-conducting state”, allowing the flowing of a current between conductive regions 101a, 101b, and 101d, and possibly between conductive regions 101a, 101b, and 101c, when the material of regions 105a, 105b, and 105c is in the crystalline phase.

During the switching of switch 100 between the conducting and blocked non-conducting states, the control electrodes 111-1 and 111-2 of heater elements 109a and 109b, and the control electrodes 115-1 and 115-2 of heater element 109c are for example simultaneously submitted to control voltages causing the flowing of a current through heater elements 109a, 109b, and 109c. This current causes, by Joule effect and then by radiation and/or conduction within the structure of switch 100, in particular through layers 107, a rise of the temperature of the underlying regions 105a, 105b, and 105c from their upper surfaces, located in front of the respective heater elements 109a, 109b, and 109c.

More precisely, to have switch 100 switch from the reflective non-conducting state to the conducting state, regions 105a and 105b of phase-change material are heated, by means of heater elements 109a and 109b, for example, to a temperature T1 and for a time period d1. Temperature T1 and time period d1 are selected in such a way as to cause a phase change of the material of regions 105a and 105b from the amorphous phase to the crystalline phase. Temperature T1 is, for example, higher than a crystallization temperature and lower than a melting temperature of the material of regions 105a and 105b. As an example, temperature T1 is in the range from 150 to 350° C. and time period d1 is shorter than 1 μs. In the case where regions 105a and 105b are made of germanium telluride, temperature T1 is, for example, equal to approximately 300° C. and time period d1 is, for example, in the range from 100 ns to 1 μs.

Further, region 105c of phase-change material is heated, by means of heater element 109c, for example to a temperature T2 higher than temperature T1, and for a time period d2 shorter than time period d1. Temperature T2 and time period d2 are selected in such a way as to cause a phase change of the material of region 105c from the crystalline phase to the amorphous phase. Temperature T2 is, for example, higher than the melting temperature of the phase-change material. As an example, temperature T2 is in the range from 600 to 1,000° C. and time period d2 is shorter than 500 ns. If region 105c is made of germanium telluride, temperature T2 is, for example, around 700° C. and time period d2 is, for example, around 100 ns.

During the switching of switch 100 between the reflective non-conducting state and the conducting state, heater element 105c and heater elements 105a and 105b are controlled simultaneously, for example. This advantageously enables to decrease the switching time.

Conversely, to have switch 100 switch from the conducting state to the reflective non-conducting state, regions 105a and 105b are heated, by means of heater elements 109a and 109b, for example to temperature T2 and for time period d2. On the other hand, region 105c is heated, by means of heater element 109c, for example to temperature T1 and for time period d1.

Thus, during the switching between the conducting state and the reflective non-conducting state, heater elements 109 (109a, 109b) and 109c are for example controlled simultaneously and in opposition. As an example, heater element 109c is intended to be controlled in such a way as to switch region 105c of phase-change material from a first state to a second state (for example, from the crystalline state to the amorphous state) when heater element 109 (109a, 109b) is controlled in such a way as to switch regions 105a and 105b of phase-change material from the second to the first state (from the amorphous state to the crystalline state, in this example).

The switching between the reflective non-conducting and absorbing non-conducting states is, for example, similar to the above-described switching between the conducting and non-conducting states, with the difference that only heater elements 109a and 109b are implemented for the switching between the reflective non-conducting and absorbing non-conducting states, the material of region 105c remaining in the crystalline phase during this switching. For example, to have switch 100 switch from the reflective non-conducting state to the absorbing non-conducting state, regions 105a and 105b are heated to temperature T1 and for time d1. Conversely, to have switch 100 switch from the absorbing non-conducting state to the reflective non-conducting state, regions 105a and 105b are, for example, heated to temperature T2 and for time period d2.

Further, the switching between the conducting and absorptive non-conducting states is similar to the switching between the conducting and reflective non-conducting states described hereabove, with the difference that only heater element 105c is used to switch between the conducting and absorbing non-conducting states, while the material of regions 105a and 105b remains in the crystalline phase during this switching. For example, to have switch 100 switch from the conducting state to the absorbing non-conducting state, region 105c is heated to temperature T1 and for time period d1. Conversely, to have switch 100 switch from the absorbing non-conducting state to the conducting state, region 105c is heated, for example, to temperature T2 and for time period d2.

The values of temperatures T1 and T2 and of heating times d1 and d2 may be identical for each of regions 105a, 105b, 105c. As a variant, at least one of regions 105a, 105b, 105c, for example region 105c, may have values of temperature T1 and/or T2 and/or of heating time d1 and/or d2 different from those of the other regions (regions 105a and 105b, in this example).

Switch 100 is said to be “indirectly heated”, the temperature rise in the phase-change material being obtained by the flowing of a current through a heater element electrically-insulated from the phase-change material, as opposed to switches of “direct heating” type which comprise no heater element and in which the temperature rise results from the flowing of a current through the phase-change material. In the case of a direct-heating switch, the control electrodes are, for example, connected to two opposite sides of the region of phase-change material, for example along a direction orthogonal to the conduction path of the switch. A disadvantage of direct-heating switches lies in the fact that, when the switch is conducting, an electrical conduction path is created through the phase-change material between the control electrodes and the conduction electrodes of the switch. This results in leakage currents, which disturb the signal transmitted between the conduction electrodes.

In the shown example, conductive region 101b is at a floating potential when regions 105a, 105b, and 105c are in the amorphous (non-conducting) state. Conductive region 101b is, for example, only connected to regions 105a, 105b, and 105c of phase-change material.

An advantage of switch 100 lies in the fact that the reflective non-conducting state enables to obtain a better insulation, for example improved by approximately-20 dB, between conductive regions 101a and 101c as compared with the case of a similar switch but comprising a single region of phase-change material coupling two conductive electrodes. Another advantage of switch 100 lies in the fact that it is possible to take advantage of the absorbing non-conducting state to attenuate the signal transmitted between conductive regions 101a and 101c.

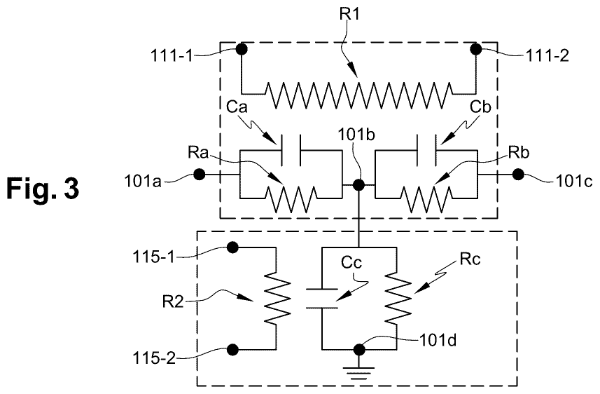

FIG. 3 is a circuit diagram equivalent to the switch 100 of FIGS. 1A and 1B.

In the shown example:
region 105a of phase-change material is symbolized by a resistive element Ra and a capacitive element Ca associated in parallel between conductive regions 101a and 101b;
region 105b of phase-change material is symbolized by a resistive element Rb and a capacitive element Cb associated in parallel between conductive regions 101b and 101c; and
region 105c of phase-change material is symbolized by a resistive element Rc and a capacitive element Cc associated in parallel between conductive regions 101b and 101c.

Resistive elements Ra, Rb, and Rc symbolize the electrical resistance of the regions of phase-change material 105a, 105b, and 105c of switch 100. The resistance of each resistive element Ra, Rb, and Rc varies according to whether the corresponding region 105a, 105b, 105c is in the crystalline or amorphous state. More precisely, the resistance of each resistive element Ra, Rb, Rc may, for example, take:
a first value Ra_on, Rb_on, Rc_on corresponding to the resistance of the resistive element Ra, Rb, Rc when the corresponding region of phase-change material 105a, 105b, 105c is in the crystalline state; and
a second value Ra_off, Rb_off, Rc_off greater than the first value Ra_on, Rb_on, Rc_on and corresponding to the resistance of the resistive element Ra, Rb, Rc when the corresponding region of phase-change material 105a, 105b, 105c is at least partially in the amorphous state.

As an example, in a case where the regions of phase-change material 105a, 105b, and 105c are made of germanium telluride, ratios Ra_off/Ra_on, Rb_off/Rb_on, Rc_off/Rc_on are in the order of 10⁵. In this case, the volume of each region 105a, 105b, 105c is, for example, sized so that values Ra_on, Rb_on and Rc_on are substantially equal, and values Ra_off, Rb_off and Rc_off are substantially equal.

As a variant, in a case where the regions of phase-change material 105a, 105b, and 105c are made of GST, ratios Ra_off/Ra_on, Rb_off/Rb_on, Rc_off/Rc_on are, for example, in the order of 10², that is, much lower than the ratios obtained in the example where regions 105a, 105b, and 105c are made of germanium telluride. In this case, the volume of each region 105a, 105b, 105c is, for example, sized so that value Rc_on is, for example, from 10 to 50 times greater than each value Ra_on, Rb_on, and that value Rc_off is, for example, from 10 to 50 times greater than each value Ra_off, Rb_off. Region 105c then has, for example, a volume smaller than that of regions 105a and 105b. This enables to compensate for the fact that ratios Ra_off/Ra_on, Rb_off/Rb_on, Rc_off/Rc_on are in this case smaller than in the case where regions 105a, 105b, and 105c are made of germanium telluride. As an example, in the case where regions 105a, 105b, and 105c are made of GST:
values Ra_on and Rb_on are in the range from 0.5 to 5Ω, for example equal to approximately 1Ω;
values Ra_off and Rb_off are in the range from 50 to 500Ω, for example equal to approximately 100Ω;
value Rc_on is in the range from 5 to 250Ω, for example equal to approximately 20Ω; and
value Rc_off is in the range from 500 to 25,000Ω, for example equal to approximately 2,000Ω.

The presence of the capacitive elements Ca, Cb, and Cc lies in the fact that the regions of phase-change material 105a, 105b, and 105c are separated from heater elements 109a, 109b, and 109c, respectively, by insulating layer 107. As an example, when the corresponding region 105a, 105b, 105c is in the amorphous phase, each capacitive element Ca, Cb, Cc has a capacitance in the order of 10 fF.

Further, in the shown example, conductive track 113, having heater elements 109a and 109b formed therein, is symbolized by a resistive element R1 connected between control electrodes 111-1 and 111-2, and conductive track 117, having heater element 109c formed therein, is symbolized by a resistive element R2 connected between control electrodes 115-1 and 115-2.

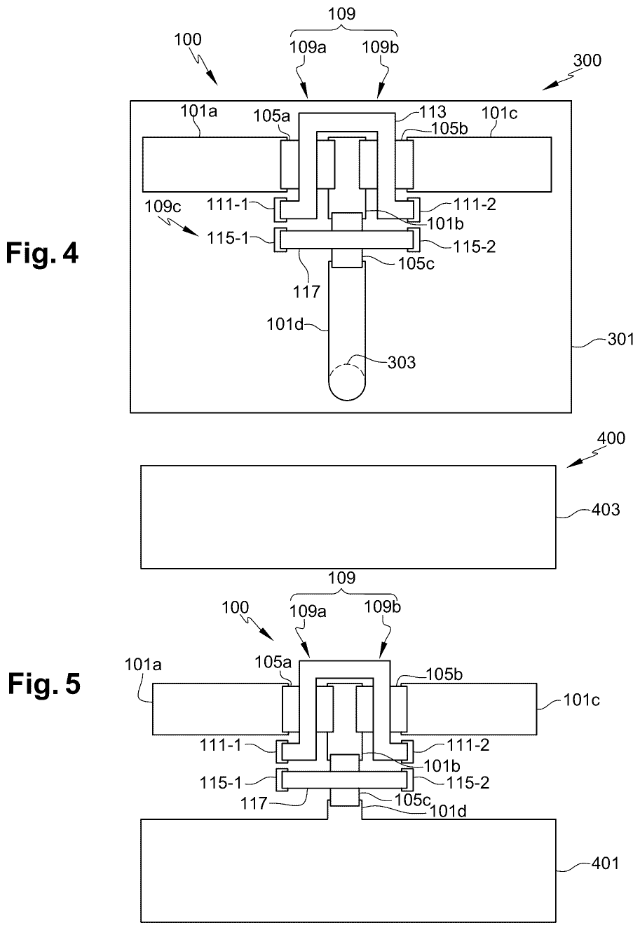

FIG. 4 is a simplified and partial top view of an example of a microstrip line 300 comprising the switch 100 of FIGS. 1A and 1B according to an embodiment.

In the shown example, switch 100 is located vertically in line with a ground plane 301. The conductive region 101d of switch 100 is connected to the underlying ground plane 301 by a conductive via 303, for example a metal via.

The implementation of switch 100 in microstrip line 300 enables to obtain an insulation greater than that which would be obtained with a switch devoid of region 105c, of conductive region 101d, and of via 303, for example, a switch comprising a single region of phase-change material coupling conductive regions 101a and 101c.

FIG. 5 is a simplified and partial top view of an example of a coplanar line or waveguide (CPW) 400 comprising the switch 100 of FIGS. 1A and 1B according to an embodiment.

In the shown example, switch 100 is laterally interposed between two ground planes 401 and 403. The ground planes 401 and 403 and the conductive regions 101a, 101b, 101c, and 101d of switch 100 are, for example, coplanar. In the illustrated example, the conductive region 101d of switch 100 is connected to ground plane 401.

The implementation of switch 100 in coplanar line 400 enables to obtain an insulation greater than that which would be obtained with a switch devoid of region 105c, of conductive region 101d, and of via 303, for example, a switch comprising a single region of phase-change material coupling conductive regions 101a and 101c.

Although FIGS. 4 and 5 illustrate embodiments where switch 100 comprises no control electrode 111-3, control electrode 111-3 may, as a variant, be provided as in the example discussed hereabove in relation with FIGS. 1A and 1B.

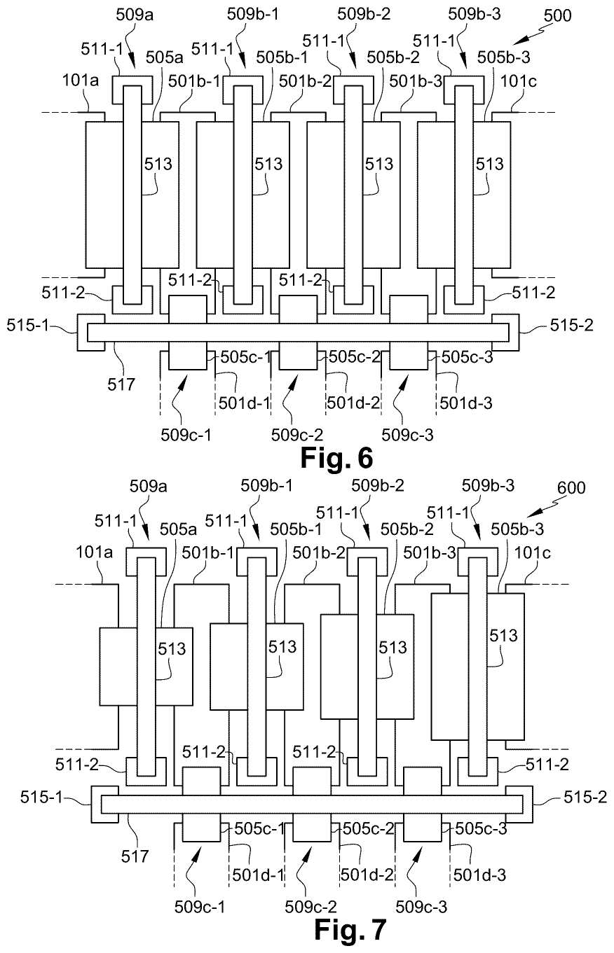

FIG. 6 is a simplified and partial top view of an example of a switch 500 based on a phase-change material according to an embodiment.

The switch 500 of FIG. 6 comprises elements common with the switch 100 of FIGS. 1A and 1B. These common elements will not be detailed again hereafter.

The switch 500 of FIG. 6 differs from the switch 100 of FIGS. 1A and 1B in that the switch 500 of FIG. 6 comprises a plurality of intermediate conductive regions 501b (three intermediate conductive regions 501b-1, 501b-2, and 501b-3, in the shown example) laterally interposed between conductive regions 101a and 101c. Each conductive region 501b is, for example, similar or identical to the conductive region 101b of switch 100. In the shown example, switch 500 comprises regions 505a, 505b-1, 505b-2, and 505b-3 of phase-change material. Region 505a couples conductive regions 101a and 501b-1, region 505b-1 couples conductive regions 501b-1 and 501b-2, region 505b-2 couples conductive regions 501b-2 and 501b-3, and region 505b-3 couples conductive regions 501b-3 and 101c. Each region 505a, 505b-1, 505b-2, 505b-3 is, for example, similar or identical to the regions 105a and 105b of switch 100.

In the shown example, switch 500 further comprises a plurality of conductive regions 501d (three conductive regions 501d-1, 501d-2, and 501d-3, in the shown example) located respectively in front of conductive regions 501b. Each conductive region 501d is, for example, similar or identical to the conductive region 101d of switch 100. In the shown example, switch 500 further comprises regions 505c-1, 505c-2, and 505c-3 of phase-change material. Region 505c-1 couples conductive regions 501b-1 and 501d-1, region 505c-2 couples conductive regions 501b-2 and 501d-2, and region 505c-3 couples conductive regions 501b-3 and 501d-3. Each region 505c-1, 505c-2, 505c-3 is, for example, similar or identical to the regions 105c of switch 100.

In the example illustrated in FIG. 6, switch 500 further comprises heater elements 509a, 509b-1, 509b-2, and 509b-3 located respectively vertically in line with the regions of phase-change material 505a, 505b-1, 505b-2, and 505b-3. Each heater element 509a, 509b-1, 509b-2, 509b-3 is connected between control electrodes 511-1 and 511-2 located on either side of the conduction direction. In this example, each heater element 509a, 509b-1, 509b-2, 509b-3 forms part of a conductive track 513, for example a metal track, having its upper and lower ends respectively connected to control electrodes 511-1 and 511-2. Heater elements 509a, 509b-1, 509b-2, and 509b-3 are, for example, intended to be simultaneously controlled.

In the illustrated example, heater elements 509a, 509b-1, 509b-2, and 509b-3 are insulated from each other. As a variant, heater elements 509a, 509b-1, 509b-2, and 509b-3 may be connected, for example by means of a conductive track interconnecting the electrodes 511-1 of heater elements 509a, 509b-1, 509b-2, and 509b-3.

In the illustrated example, switch 500 further comprises heater elements 509c (three heater elements 509c-1, 509c-2, and 509c-3, in the shown example) series-connected between control electrodes 515-1 and 515-2 and forming part of a same conductive track 517, for example a metal track, having its left and right ends respectively connected to control electrodes 515-1 and 515-2. Heater elements 509c-1, 509c-2, and 509c-3 are intended to be simultaneously controlled, for example by the application of a potential difference between electrodes 515-1 and 515-2.

As a variant, heater elements 509c-1, 509c-2, and 509c-3 may be electrically insulated from each other. In this case, heater elements 509c-1, 509c-2, and 509c-3 are for example formed in separate conductive tracks, insulated from each other and each connected between control electrodes similar to electrodes 515-1 and 515-2. In this case, the control electrodes of each heater element 509c-1, 509c-2, 509c-3 are, for example, parallel to the conduction direction of switch 500. Heater elements 509c-1, 509c-2, and 509c-3 may, in this variant, be simultaneously controlled, for example by the simultaneous application of a potential difference between the control electrodes of each heater element 509c-1, 509c-2, 509c-3.

Heater elements 509c-1, 509c-2, and 509c-3 are electrically insulated from heater elements 509a, 509b-1, 509b-2, and 509b-3. This enables to control heater elements 509c-1, 509c-2, and 509c-3 independently from heater elements 509a, 509b-1, 509b-2, and 509b-3 as discussed hereabove in relation with FIGS. 1A and 1B for switch 100.

The operation of the switch 500 of FIG. 6 is similar to the operation of the switch 100 of FIGS. 1A to 1B. Those skilled in the art are capable, based on the indications of the present disclosure, of controlling the heater elements 509a, 509b-1, 509b-2, 509b-3, 509c-1, 509c-2, and 509c-3 of switch 500 to obtain conducting, reflective non-conducting, and absorptive non-conducting states similar to those previously described in relation with FIGS. 1A and 1B for switch 100. Switch 500 has advantages similar or identical to those of switch 100.

The fact of providing a plurality of regions 505a, 505b-1, 505b-2, and 505b-3 made of phase-change material advantageously enables to decrease the amount of electrical energy and the time period required for each switching, while enabling, in the non-conducting state, to reach a high breakdown voltage, for example, greater than or equal to 4 V, between the conductive regions 101a and 101c of switch 500. Switch 500 thus has, as compared with switch 100, a higher switching speed, a lower power consumption, and a greater reliability.

FIG. 7 is simplified and partial top view of an example of a switch 600 based on a phase-change material according to an embodiment.

The switch 600 of FIG. 7 has elements in common with the switch 500 of FIG. 6. These common elements will not be detailed again hereafter.

The switch 600 of FIG. 7 differs from the switch 500 of FIG. 6 in that the regions of phase-change material 505a, 505b-1, 505b-2, and 505b-3 of switch 600 have, in top view, different areas. In the shown example, regions 505a, 505b-1, 505b-2, and 505b-3 have, along the conduction direction of switch 600, from conductive region 101a to conductive region 101c, increasing areas. In the shown example, the regions of phase-change material 505a, 505b-1, 505b-2, and 505b-3 have the same length, to within manufacturing dispersions, and different widths, for example increasing between the two conductive regions 101a and 101c of switch 600. As an example, the conductive region 101c in contact with region 505b-3 having the largest area is adapted to being taken to a high potential, for example higher than or equal to 4 V, the other conductive region 101a, in contact with the region 505a having the smallest area, in this example, being intended to be taken to a reference potential, for example ground. Further, the difference in areas, or widths, between two successive regions 505a, 505b-1, 505b-2, 505b-3 is all the greater as regions 505a, 505b-1, 505b-2, 505b-3 are close to the conductive region 101c in contact with the region 505b-3 having the largest area (close to the right end, in the orientation of FIG. 7).

The width, or area, of each region 505a, 505b-1, 505b-2, 505b-3 is for example determined so that, when switch 600 is in the off state and a voltage, resulting from the application of the radio frequency signal, is applied between its conductive regions 101a and 101c, the resulting voltages individually applied to each region 505a, 505b-1, 505b-2, 505b-3, that is, for each region 505a, 505b-1, 505b-2, 505b-3, the voltage applied between the two conductive regions that it couples, are substantially identical, or balanced. This advantageously enables to improve the breakdown voltage of switch 600 as compared with switch 500.

Various embodiments and variants have been described. Those skilled in the art will understand that certain features of these various embodiments and variants may be combined, and other variants will occur to those skilled in the art. In particular, those skilled in the art are capable, in microstrip line 300 or in coplanar line 400, of replacing switch 100 with switch 500 or with switch 600.

Finally, the practical implementation of the described embodiments and variants is within the abilities of those skilled in the art based on the functional indications given hereabove. In particular, those skilled in the art are capable, based on the indications of the present disclosure, of selecting the material and of sizing the volume of each region of phase-change material according to the desired electrical characteristics.

1. Switch comprising:
first, second, third, and fourth conductive regions;
a first region made of a phase-change material coupling the first and second conductive regions;
a second region made of a phase-change material coupling the second and third conductive regions; and
a third region made of a phase-change material coupling the second and fourth conductive regions, the third conductive region being intended to be taken to a reference potential, preferably the ground,
wherein the first and second regions of phase-change material are intended to transmit a radio frequency signal.

2. Switch according to claim 1, wherein:
the first and third conductive regions form conduction electrodes of the switch; and
the fourth conductive region forms a reference electrode of the switch.

3. Switch according to claim 1, further comprising first, second, and third heater elements respectively located in front of first, second, and third regions of phase-change material, each heater element being electrically insulated from said region located in front of it.

4. Switch according to claim 3, wherein the first and second heater elements form a single heater element.

5. Switch according to claim 3, wherein the third heater element is intended to be controlled independently from the first and second heater elements.

6. Switch according to claim 3, wherein the first and second heater elements are intended to be controlled simultaneously.

7. Switch according to claim 3, wherein the first and second heater elements are series-connected between first and second control electrodes.

8. Switch according to claim 7, wherein:
the first heater element is connected between the first control electrode and a third control electrode; and
the second heater element is connected between the second control electrode and the third control electrode.

9. Switch according to claim 3, wherein the third heater element is intended to be controlled in such a way as to have the third region of phase-change material change from a first state to a second state when the first and second heater elements are controlled in such a way as to have the first and second regions of phase-change material change from the second to the first state.

10. Switch according to claim 1, wherein the first, second, and third regions of phase-change material are made of a chalcogenide material.

11. Switch according to claim 10, wherein each of the first, second, and third regions of phase-change material is made of germanium telluride or of germanium-antimony-telluride.

12. Switch according to claim 1, wherein the third region of phase-change material has a volume smaller than that of the first and second regions of phase-change material.

13. Switch according to claim 1, wherein the first and second regions of phase-change material have, in top view, different areas.

14. Switch according to claim 1, wherein the first and second regions of phase-change material have, along the switch conduction direction, a same lateral dimension.

15. Switch according to claim 1, wherein the first and second regions of phase-change material have, along a direction orthogonal to the switch conduction direction, different lateral dimensions.

16. Device comprising a switch according to claim 1 and a ground plane having the fourth conductive region of the switch connected thereto.
